(19) United States
(12) Patent Application Publication
(10) Pub. No.: US 2025/0098129 A1
(43) Pub. Date: Mar. 20, 2025

(54) SPEAKER MODULE HAVING MAGNETIC FIELD SHIELDING STRUCTURE AND ELECTRONIC DEVICE INCLUDING SAME

(71) Applicant: Samsung Electronics Co., Ltd., Suwon-si (KR)

(72) Inventors: Sangmin YE, Suwon-si (KR); Byunggun CHOI, Suwon-si (KR); Kwanhee HAN, Suwon-si (KR)

(73) Assignee: Samsung Electronics Co., Ltd., Suwon-si (KR)

(21) Appl. No.: 18/970,131

(22) Filed: Dec. 5, 2024

Related U.S. Application Data
(63) Continuation of application No. PCT/KR2023/009251, filed on Jun. 30, 2023.

(30) Foreign Application Priority Data
Jul. 6, 2022 (KR) 10-2022-0083004
Aug. 12, 2022 (KR) 10-2022-0101201

(51) Int. Cl. H05K 9/00; H04R 1/02; H04R 9/06

(52) U.S. Cl. CPC H05K 9/0075; H04R 1/025; H04R 1/028; H04R 9/06; H04R 2499/11; H04R 2499/15

(57) ABSTRACT

A speaker module includes a speaker housing including a first speaker housing defining at least one first surface of the speaker module and a second speaker housing defining at least one second surface of the speaker module that is opposite to the least one first surface, a speaker assembly including a voice coil and a vibration member, the speaker assembly being accommodated in an interior of the speaker housing, a back volume in an interior of the speaker housing and defined by the first speaker housing and the second speaker housing, and a side surface shield member between an inner surface of the speaker assembly and the back volume, the side surface shield member including a ferrite-based magnetic substance, where at least one vent hole communicating the speaker assembly and the back volume is in the side surface shield member.

### CROSS-REFERENCE TO RELATED APPLICATION(S)

This application is a bypass continuation of International Application No. PCT/KR2023/009251, filed on Jun. 30, 2023, in the Korean Intellectual Property Receiving Office, which is based on and claims priority to Korean Patent Application No. 10-2022-0101201, filed on Aug. 12, 2022, in the Korean Intellectual Property Office, and Korean Patent Application No. 10-2022-0083004, filed on Jul. 6, 2022, in the Korean Intellectual Property Office, the disclosures of which are incorporated by reference herein in their entireties.

### BACKGROUND

### 1. Field

The disclosure relates to a speaker module including a magnetic field shielding structure, and an electronic device including the same.

### 2. Description of Related Art

With the development of information technology (IT), various types of electronic devices, such as smartphones and tablet personal computers (PCs), are being widely distributed. Electronic devices may provide various functions, such as a call function, a music output function, a photo taking function, an Internet access function, and the like.

The electronic device may include various components for providing various functions. For example, a speaker for outputting sound included in contents, and the like to an outside may be provided in an interior of the electronic device. In addition, to maximize a space utilization of an interior of the electronic device, various components provided in the interior of the electronic device may be disposed adjacent to or to overlap each other.

The above information is presented as background information only to assist with an understanding of the disclosure. No determination has been made, and no assertion is made, as to whether any of the above might be applicable as prior art with regard to the disclosure.

### SUMMARY

Additional aspects will be set forth in part in the description which follows and, in part, will be apparent from the description, or may be learned by practice of the presented embodiments.

According to an aspect of an embodiment, a speaker module may include a speaker housing including a first speaker housing defining at least one first surface of the speaker module and a second speaker housing defining at least one second surface of the speaker module that is opposite to the least one first surface, a speaker assembly including a voice coil and a vibration member, the speaker assembly being accommodated in an interior of the speaker housing, a back volume in an interior of the speaker housing and defined by the first speaker housing and the second speaker housing, and a side surface shield member between an inner surface of the speaker assembly and the back volume, the side surface shield member including a ferrite-based magnetic substance, where at least one vent hole communicating the speaker assembly and the back volume is in the side surface shield member.

A first end of the side surface shield member may contact the first speaker housing or the second speaker housing, and a second end of the side surface shield member may protrude toward the interior of the speaker housing, the second end being opposite to the first end.

The speaker module may include an upper shield member connected to the second end of the side surface shield member, and between an upper surface of the speaker assembly and the back volume.

The upper shield member may be spaced apart from an upper end surface of the speaker assembly by a predetermined interval.

The speaker module may include a first sound output opening in an area corresponding to the first speaker housing and a second sound output opening in an area corresponding to the upper shield member, the second sound output opening communicating the speaker assembly and the first sound output opening, where a sound signal generated by the speaker assembly is radiated to an outside via the second sound output opening and the first sound output opening.

The side surface shield member may include at least one of a first shield wall between a first side surface of the speaker assembly and the speaker housing, a second shield wall between a second side surface of the speaker assembly that is opposite to the first side surface and the speaker housing, a third shield wall between a third side surface of the speaker assembly that is connected from one end of the first side surface to one end of the second side surface and the speaker housing, and a fourth shield wall between a fourth side surface of the speaker assembly that is opposite to the third side surface and the speaker housing, and the at least one vent hole may be in at least one of the first shield wall, the second shield wall, the third shield wall, and the fourth shield wall.

At least one of the first shield wall, the second shield wall, the third shield wall, and the fourth shield wall may include a reference portion having a first height being smaller than a height of the speaker assembly, and an expansion portion on the reference portion, where the reference portion and the expansion portion together have a second height that is greater than or equal to the height of the speaker assembly, and where at least one vent hole is in the expansion portion.

The at least one vent hole may be in the reference portion.

The upper shield member may include the ferrite-based magnetic substance.

The side surface shield member may be spaced apart from the inner surface of the speaker assembly by a predetermined interval.

According to an aspect of an embodiment, an electronic device may include a housing, a main board on the housing, and a speaker module on the main board, where the speaker module may include a speaker housing including a first speaker housing defining at least one first surface of the speaker module and a second speaker housing defining at least one second surface of the speaker module that is opposite to the at least one first surface, a speaker assembly including a voice coil and a vibration member, the speaker assembly being accommodated in an interior of the speaker housing, a back volume in an interior of the speaker housing and defined by the first speaker housing and the second speaker housing, and a side surface shield member between an inner surface of the speaker assembly and the back volume, the side surface shield member including a ferrite-based magnetic substance, and where at least one vent hole communicating the speaker assembly and the back volume is in the side surface shield member.

A first end of the side surface shield member may contact the first speaker housing or the second speaker housing, and a second end of the side surface shield member may protrude toward the interior of the speaker housing, the second end being opposite to the first end.

The electronic device may include an upper shield member connected to the second end of the side surface shield member, and between an upper surface of the speaker assembly and the back volume.

A first sound output opening may be in an area of the first speaker housing and a speaker hole communicated with the first sound output opening may be in the housing.

A second sound output opening communicating the speaker assembly and the first sound output opening may be in an area of the upper shield member.

The upper shield member may include the ferrite-based magnetic substance.

The side surface shield member may include at least one of a first shield wall between a first side surface of the speaker assembly and the speaker housing, a second shield wall between a second side surface of the speaker assembly that is opposite to the first side surface and the speaker housing, a third shield wall between a third side surface of the speaker assembly that is connected from one end of the first side surface to one end of the second side surface and the speaker housing, and a fourth shield wall between a fourth side surface of the speaker assembly that is opposite to the third side surface and the speaker housing, and the at least one vent hole may be in at least one of the first shield wall, the second shield wall, the third shield wall, and the fourth shield wall.

The at least one vent hole may be in the second shield wall and is spaced apart from at least one of a plurality of components mounted on the main board that generates a magnetic field.

At least one of the first shield wall, the second shield wall, the third shield wall and the fourth shield wall may include a reference portion having a first height being smaller than a height of the speaker assembly, and an expansion portion on the reference portion, where the reference portion and the expansion portion together have a second height that is greater than or equal to the height of the speaker assembly, and at least one vent hole is in the expansion portion.

At least one vent hole may be in the reference portion.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an electronic device in a network environment according to one or more embodiments;

FIG. 2A is a perspective view of a speaker assembly according to one or more embodiments;

FIG. 2B is a cross-sectional view of the speaker assembly illustrated in FIG. 2A, taken along line A-A, according to one or more embodiments;

FIG. 3A is a perspective view of a speaker module according to one or more embodiments;

FIG. 3B is an exploded perspective view of a speaker module according to one or more embodiments;

FIG. 3C is a cross-sectional view of the speaker module taken along line B-B according to one or more embodiments;

FIG. 3D is an exploded perspective view of an electronic device including a speaker module according to one or more embodiments;

FIG. 4A is a diagram illustrating a speaker module having a magnetic field shielding structure according to one or more embodiments;

FIG. 4B is a diagram illustrating a shielding structure included in a speaker module according to one or more embodiments;

FIG. 4C is a diagram illustrating a cross-sectional view of an electronic device including a speaker module including the speaker assembly illustrated in FIG. 4B, taken along line C-C, according to one or more embodiments;

FIG. 5A to FIG. 5C are diagrams illustrating a speaker module having a magnetic field shielding structure according to one or more embodiments;

FIG. 5D is a cross-sectional view of an electronic device having a speaker module including a shield member having at least one vent hole formed therein, taken along line C-C, according to one or more embodiments;

FIG. 6A is a diagram illustrating a speaker module having a magnetic field shielding structure according to one or more embodiments;

FIG. 6B is a cross-sectional view of an electronic device having the speaker module illustrated in FIG. 6A, taken along line C-C, according to one or more embodiments; and

FIG. 7 is a diagram comparing a magnetic field shielding performance of shield members.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. It is to be understood that singular forms include plural referents unless the context clearly dictates otherwise. The terms including technical or scientific terms used in the disclosure may have the same meanings as generally understood by those skilled in the art.

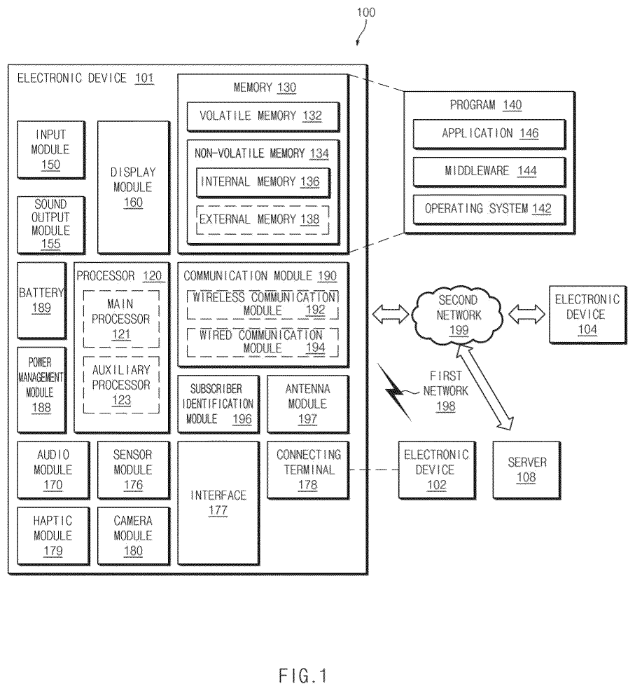

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mm Wave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

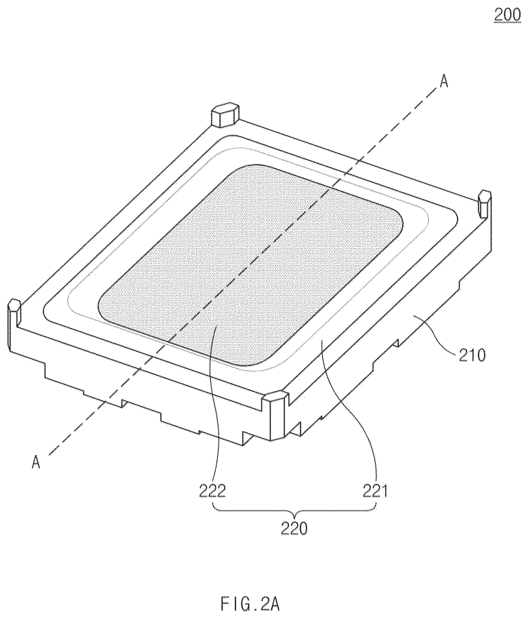

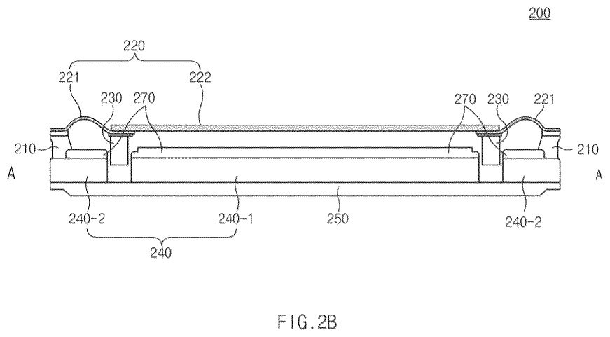

FIG. 2A is a perspective view of a speaker assembly according to one or more embodiments. FIG. 2B is a cross-sectional view of the speaker assembly illustrated in FIG. 2A, taken along line A-A, according to one or more embodiments.

A speaker assembly 200 that will be mentioned in the following description may refer to a device that is included in an electronic device (e.g., the electronic device 101 of FIG. 1) to output sound. For example, the speaker assembly 200 may be the sound output module 155 of FIG. 1.

According to one or more embodiments, as illustrated in FIGS. 2A and 2B, various components included in the speaker assembly 200 may be supported by a unit frame 210. A shape of the unit frame 210 illustrated in FIGS. 2A and 2B is merely an example, and the shape of the unit frame 210 is not limited to the shape illustrated in FIGS. 2A and 2B. The unit frame 210 may be manufactured in various shapes depending on a space, in which the speaker assembly 200 is to be disposed.

According to one or more embodiments, the speaker assembly 200 may include a vibration member 220 and a voice coil 230.

According to one or more embodiments, the voice coil 230 may be formed by winding an electric wire. The voice coil 230 may vibrate upward and downward by a magnetic field that is formed by a current that flows in the voice coil 230 and a repulsive force with magnet 240 that is adjacent to the voice coil 230. The vibration of the voice coil 230 may be controlled by the current that flows in the voice coil 230.

According to one or more embodiments, the vibration member 220 may vibrate due to movement of the voice coil 230. The voice coil 230 may be coupled to at least a portion of the vibration member 220. According to the structural feature, the vibration member 220 may vibrate due to the vibration of the voice coil 230. A sound signal may be output due to the vibration of the vibration member 220.

According to one or more embodiments, the vibration member 220 may be supported by at least a portion of the unit frame 210. The vibration member 220 may include a first vibration portion 221 and a second vibration portion 222. At least a portion of the first vibration portion 221 may be supported by the unit frame 210. At least a portion of the second vibration portion 222 may be coupled to the first vibration portion 221.

According to one or more embodiments, the first vibration portion 221 may be formed of a flexible material (e.g., a material having a high elastic modulus). For example, the first vibration portion 221 may be formed of an elastomer, a synthetic resin, or a thin metal plate.

According to one or more embodiments, the second vibration portion 222 may be formed of a material (e.g., a material having a relatively higher elastic modulus than that of the first vibration portion 221) that is relatively harder than the first vibration portion 221. For example, the second vibration portion 222 may be formed of a metal, a synthetic resin, or an alloy.

According to one or more embodiments, as illustrated in FIG. 2A, the first vibration portion 221 may be disposed at an outer periphery of the unit frame 210, and the second vibration portion 222 may be supported by the first vibration portion 221. According to the structural features, the first vibration portion 221 may vibrate due to the movement of the voice coil 230 that is coupled to the vibration member 220, and the second vibration portion 222 supported on the first vibration portion 221 may vibrate together with the vibration of the first vibration portion 221, thereby generating a sound signal. However, this is merely exemplary, and the embodiments are not limited thereto. For example, the vibration member 220 may be formed as a single vibration portion while not being divided into the first vibration portion 221 and the second vibration portion 222.

According to one or more embodiments, the speaker assembly 200 may include a yoke 250 that defines a lower portion of the speaker assembly 200. The yoke 250 may be formed of a magnetic material, and may prevent a magnetic field generated in an interior of the speaker assembly 200 from being leaked to the outside of the speaker assembly 200, and conversely, may prevent a magnetic field generated on the outside of the speaker assembly 200 from being introduced into the speaker assembly 200. For example, the yoke 250 may be formed of a magnetic metal or a material including a magnetic metal.

According to one or more embodiments, a magnet 240 may be disposed in the yoke 250. The magnet 240 may include a first magnet 240-1 and a second magnet 240-2. As illustrated in FIG. 2B, the first magnet 240-1 may be disposed at a central portion of the yoke 250, and the second magnet 240-2 may be disposed on a side portion of the yoke 250. The voice coil 230 may be disposed between the first magnet 240-1 and the second magnet 240-2.

According to one or more embodiments, at least a portion of the magnet 240 may be covered by a plate 270. The plate 270 may be formed of a material that may shield a magnetic flux.

According to one or more embodiments, the magnet 240, the yoke 250, and the plate 270 may form a magnetic circuit for driving the speaker assembly 200. The voice coil 230 may vibrate due to the repulsion of a magnetic field formed by a current flow of the magnetic circuit formed by the magnet 240, the yoke 250, and the plate 270 and the voice coil 230.

A shape and a structure of the speaker assembly 200 described above are merely examples, and the speaker assembly 200 described below is not limited to the shape and the structure illustrated in FIGS. 2A and 2B. For example, at least one of the components of the speaker assembly 200 described above may be omitted, or another component (e.g., a circuit for controlling vibration of the vibration member) may be added to the configuration of the speaker assembly 200.

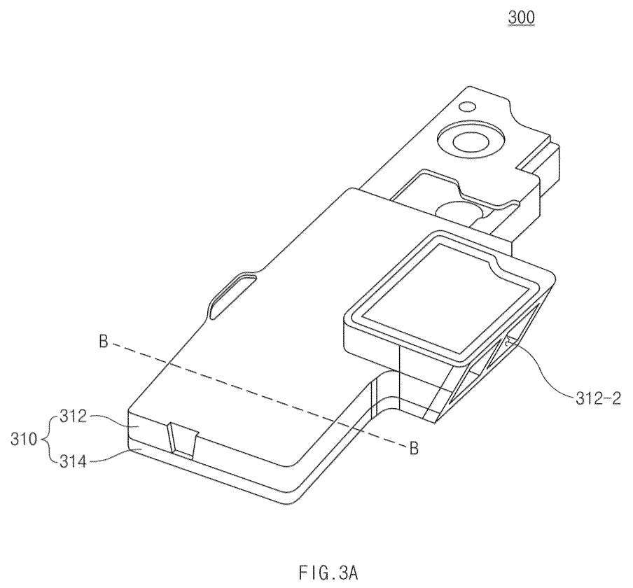

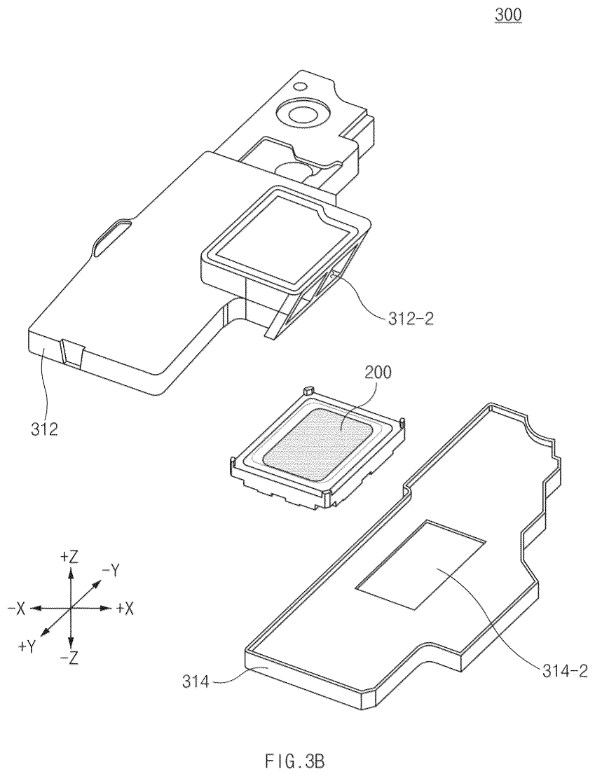

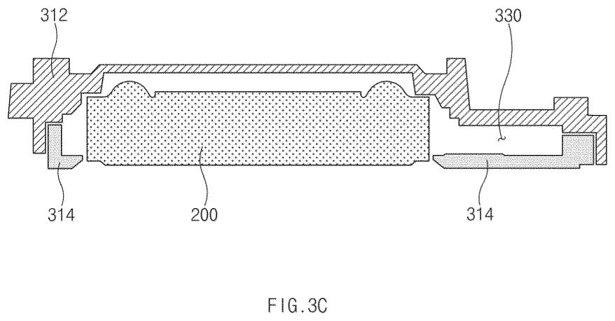

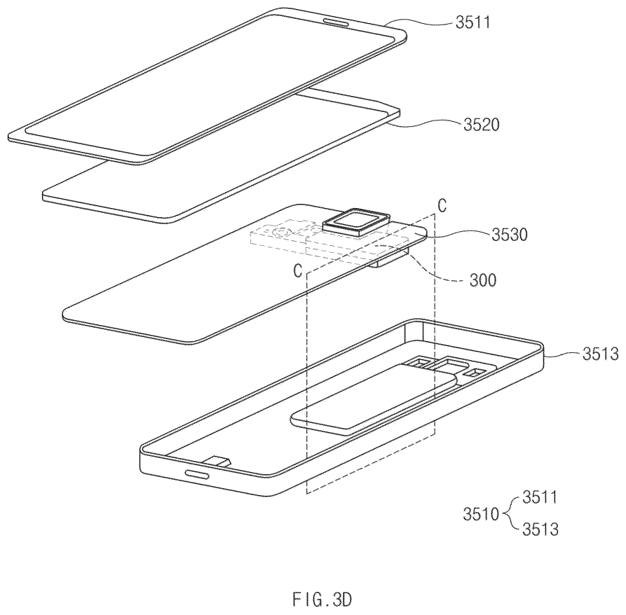

FIG. 3A is a perspective view of a speaker module according to one or more embodiments. FIG. 3B is an exploded perspective view of a speaker module according to one or more embodiments. FIG. 3C is a cross-sectional view of the speaker module taken along line B-B according to one or more embodiments. FIG. 3D is an exploded perspective view of an electronic device including a speaker module according to one or more embodiments.

Referring to FIGS. 3A to 3D, the speaker module 300 according to one or more embodiments may include a speaker assembly 200 and a speaker housing 310 that accommodates the speaker assembly 200.

According to one or more embodiments, a first sound output opening 312-2 may be formed in an area of the speaker housing 310. The first sound output opening 312-2 may be an opening that communicates an outside and an interior space of the speaker housing 310. A sound signal generated by the speaker assembly 200 may be radiated to the outside of the speaker module 300 through the first sound output opening 312-2. In this regard, a radiation path of a sound signal, along which a sound signal generated by the speaker assembly 200 through the first sound output opening 312-2 is output, may be formed in the interior of the speaker housing 310.

According to one or more embodiments, the radiation path may be defined by an inner surface of the speaker housing 310, and an outer surface of the speaker assembly 200 accommodated in the interior of the speaker housing 310. For example, the speaker assembly 200 may be accommodated while being spaced apart from the inner surface of the speaker housing 310 at a specific distance. Accordingly, a space may be defined between the inner surface of the speaker housing 310 and the outer surface of the speaker assembly 200, and the space may be used as the radiation path of a sound signal, along which a sound signal generated by the speaker assembly 200 is guided to the first sound output opening 312-2.

According to one or more embodiments, the speaker housing 310 may include a first speaker housing 312 and a second speaker housing 314. The first speaker housing 312 may cover a first surface of the speaker assembly 200 (e.g., an upper surface of the speaker assembly 200 including the vibration member 220), and the second speaker housing 314 may cover a second surface of the speaker assembly 200 (e.g., a lower surface of the speaker assembly 200 including the yoke 250).

According to one or more embodiments, a first sound output opening 312-2 may be formed in an area of the first speaker housing 312, and an accommodation portion 314-2 corresponding to a speaker assembly 200 may be formed in an area of the second speaker housing 314 to accommodate the speaker assembly 200. The second surface of the speaker assembly 200 may be accommodated in the accommodation portion 314-2 formed in the second speaker housing 314, and the first speaker housing 312 may be coupled to an upper portion of the second speaker housing 314. For example, through coupling of the first speaker housing 312 and the second speaker housing 314, a sound signal output by the speaker assembly 200 may not be leaked, but may be radiated through the first sound output opening 312-2.

According to one or more embodiments, as illustrated in FIG. 3C, a back volume 330 having a specific extent may be formed in an interior of the speaker housing 310. The back volume 330 may be defined by the first speaker housing 312 and the second speaker housing 314. The back volume 330 may generate a flow of air so that the vibration member 220 of the speaker assembly 200 may vibrate smoothly. The back volume 330 may improve the reproduction characteristics in a specific sound range (e.g., a low sound range) by blocking a sound signal radiated in a specific direction (e.g., a rearward direction) of the speaker assembly 200. According to one or more embodiments, some of the sound signals output by the speaker assembly 200 may be directed toward the first sound output opening 312-2 in FIG. 3B along the first direction (e.g., the +X axis), and some of the sound signals may be directed toward the back volume 330 along directions (e.g., the −X axis, the +Y axis, the −Y axis, the +Z axis, and the −Z axis) other than the first direction.

According to one or more embodiments, as illustrated in FIG. 3D, the speaker module 300 may be provided in an interior of an electronic device (e.g., the electronic device 101 of FIG. 1). The interior of the electronic device may be a space, in which various electronic components included in the electronic device are disposed.

For example, the electronic device may include a housing 3510, a display 3520, a printed circuit board (or a main board) 3530, a speaker module 300, and a battery 3560. The housing 3510 may include a front cover 3511 and a rear cover 3513, and may form an external appearance of the electronic device. The front cover 3511 may define a front part of the electronic device, and the rear cover 3513 may define a side part and a rear part of the electronic device. However, this is merely exemplary, and the embodiments are not limited thereto. For example, other components not illustrated in FIG. 3D may be included as components of the electronic device, and the stacking order of the components included in the electronic device may be different from the stacking order illustrated in FIG. 3D.

According to one or more embodiments, a speaker hole may be formed in the housing 3510. The speaker hole may radiate the sound signal generated by the speaker assembly 200 to the outside of the electronic device. According to one or more embodiments, the speaker hole may communicate with the first sound output opening 312-2 of the speaker module 300. Accordingly, the sound signal generated by the speaker assembly 200 may be radiated to the outside through the first sound output opening 312-2 and the speaker hole.

According to one or more embodiments, among various components provided in an interior of the electronic device, at least some components of the speaker module 300 may be disposed adjacent to or to overlap other components. For example, at least a portion of the speaker module 300 may be disposed to overlap at least a portion of a printed circuit board 3530. However, in a structure, in which the speaker module 300 is disposed to overlap the printed circuit board 3530, the magnetic field generated by the printed circuit board 3530 may be introduced into the speaker assembly 200 and deteriorate a performance of the speaker assembly 200. For example, the magnetic field generated by the printed circuit board 3530 may generate an induced current in the voice coil 230, and thus, may cause the vibration member 220 of the speaker assembly 200 to vibrate and generate audible noise (or unintended noise).

According to one or more embodiments, the speaker module 300 may block a magnetic field generated by at least one other component provided in an interior of the electronic device from being introduced into the speaker assembly 200, as will be described later through the drawings below.

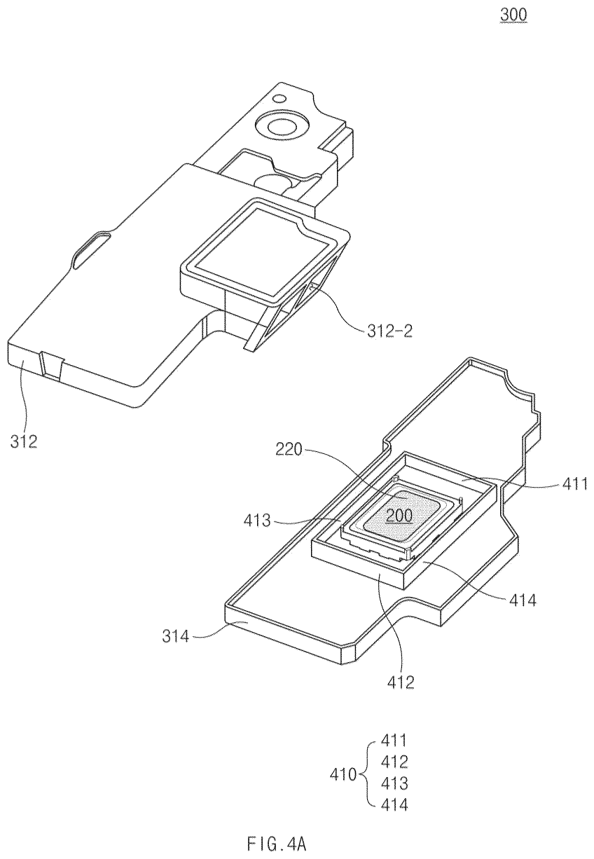

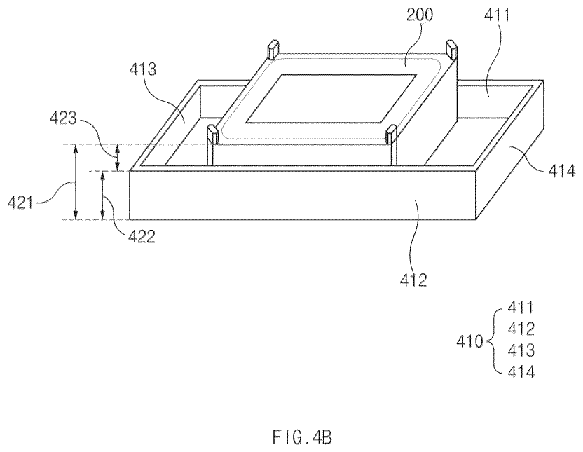

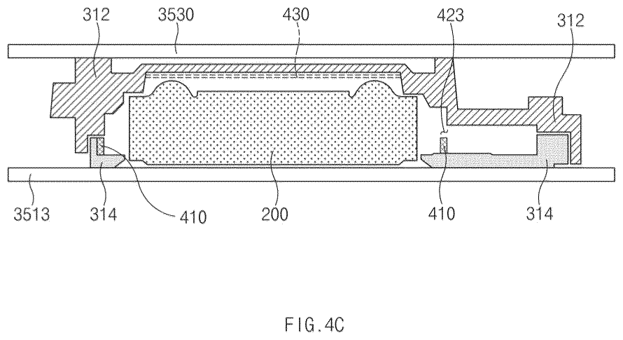

FIG. 4A is a diagram illustrating a speaker module having a magnetic field shielding structure according to one or more embodiments. FIG. 4B is a diagram illustrating a shielding structure included in a speaker module according to one or more embodiments. FIG. 4C is a diagram illustrating a cross-sectional view of an electronic device including a speaker module including the speaker assembly illustrated in FIG. 4B, taken along line C-C, according to one or more embodiments.

Referring to FIG. 4A and FIG. 4B, a speaker module 300 according to one or more embodiments may include a shield member 410 that is configured to block a magnetic field (e.g., a magnetic field generated by the printed circuit board 3530) from being introduced into the speaker assembly 200.

According to one or more embodiments, the shield member 410 may be configured in a form that surrounds a side surface of the speaker assembly 200. The shield member 410 may be formed to protrude upward from the first surface (e.g., the upper surface) of the second speaker housing 314 toward the interior of the speaker housing 310. However, this is merely exemplary, and the embodiments are not limited thereto. For example, the shield member 410 may be formed to protrude downward from the second surface (e.g., the lower surface) of the second speaker housing 314 toward the interior of the speaker housing 310.

For example, the shield member 410 may include a first shield wall 411 that is disposed to be spaced apart from a first side surface (e.g., the upper side surface) of the speaker assembly 200 by a specific interval, a second shield wall 412 that is disposed to be spaced apart from a second side surface (e.g., the lower side surface) of the speaker assembly 200, which is opposite to the first side surface, by a specific interval, a third shield wall 413 that is disposed to be spaced apart from a third side surface (e.g., the left side surface) of the speaker assembly 200, which contacts one end of the first side surface to one end of the second side surface, by a specific interval, and a fourth shield wall 414 that is disposed to be spaced apart from the fourth side surface (e.g., the right side surface) of the speaker assembly 200, which is opposite to the third side surface, by a specific interval. However, this is merely exemplary, and the embodiments are not limited thereto. For example, the shield member 410 may be configured as a portion of the first shield wall 411 to the fourth shield wall 414.

As described above, the shield member 410 may be configured to surround the side surface of the speaker assembly 200 to block a magnetic field from being introduced into the side surface of the speaker assembly 200. However, with respect to the shield member 410, the interior of the speaker module 300 may be divided into a space, in which the speaker assembly 200 is disposed, and a space, in which the back volume 330 is formed. A portion or the entirety of the space formed between the shield member 410 and the speaker housing 310 may correspond to the back volume 330. In other words, at least a portion of the air flow between the speaker assembly 200 and the back volume 330 may be cut off (or blocked) by the shield member 410, and thus, the performance of the speaker assembly 200 may deteriorated.

In this regard, the speaker module 300 according to one or more embodiments may include a shield member 410 having a first height 422 that is smaller than a height 421 of the speaker assembly 200, as illustrated in FIG. 4B, to communicate the speaker assembly 200 and the back volume 330. For example, the first to fourth shield walls 411 to 414 may be formed to have the first height 422 that is smaller than the height 421 of the speaker assembly 200. In other words, as may be seen from a cross-sectional view of FIG. 4C, taken along line C-C of the electronic device of FIG. 3D, which includes the speaker module 300 including the speaker assembly 200 illustrated in FIG. 4B, the speaker assembly 200 and the back volume 330 may be communicated with each other by a space (e.g., the communication path) 423 formed due to a difference in heights between the first shield wall 411 to the fourth shield wall 414 and the speaker assembly 200. In this regard, the first to fourth shield walls 411 to 414 may be formed to have substantially the same height, or all or some of the first to fourth shield walls 411 to 414 may be formed to have different heights.

As described above, when the height of the shield member 410 is formed as the first height 422 that is smaller than the height 421 of the speaker assembly 200, the speaker assembly 200 and the back volume 330 may be communicated with each other by a communication path 423, and a performance of the speaker assembly 200 may be maintained at a certain level, and the magnetic field may be blocked from being introduced into the speaker assembly 200. However, a situation, in which the magnetic field is introduced into the speaker assembly 200 through the communication path 423, cannot be ruled out. Furthermore, as illustrated in FIG. 4C, an additional shield member 430 may be provided between the printed circuit board 3530 and the speaker module 300 to block the magnetic field from being introduced into the speaker assembly 200. However, even in this case, the magnetic field may be introduced into the speaker assembly 200 through the communication path 423.

In this regard, the speaker module 300 according to one or more embodiments may include a shield member 410 having a height that is substantially the same as or greater than that of the speaker assembly 200 to minimize the magnetic field from being introduced into the speaker assembly 200.

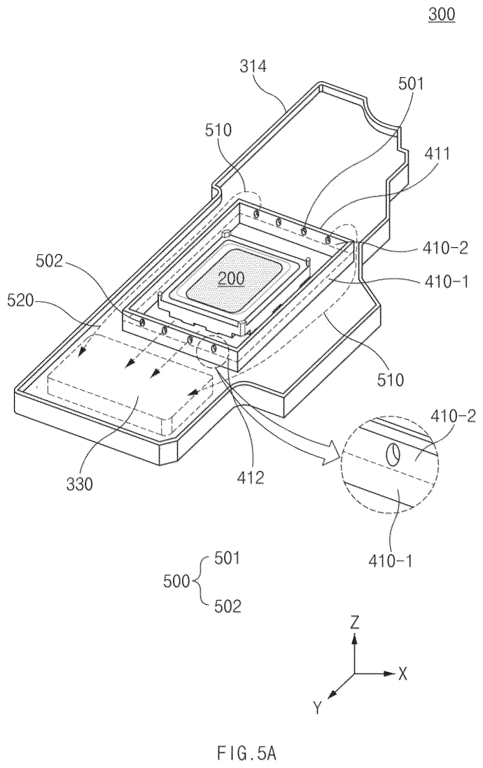

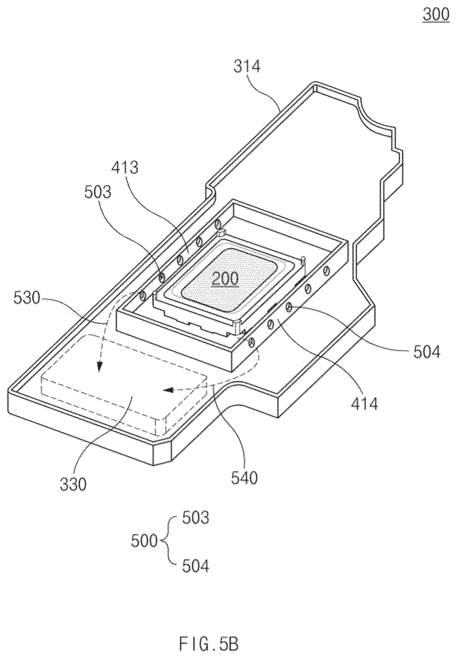

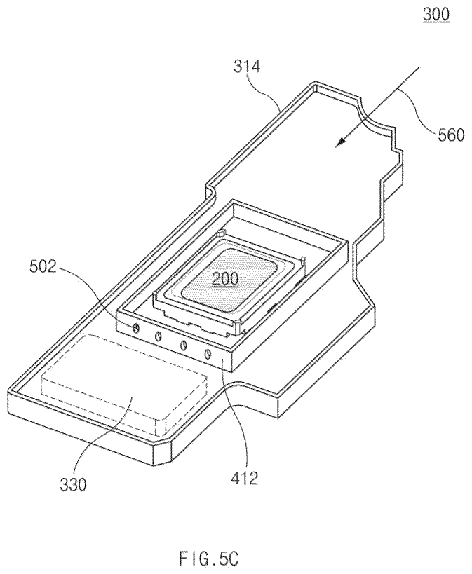

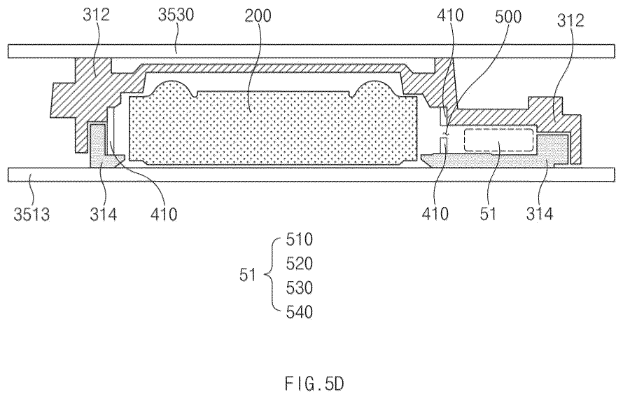

FIG. 5A to FIG. 5C are diagrams illustrating a speaker module having a magnetic field shielding structure according to one or more embodiments. FIG. 5D is a cross-sectional view of an electronic device having a speaker module including a shield member having at least one vent hole formed therein, taken along line C-C, according to one or more embodiments.

Referring to FIGS. 3A to 3D, 4A to 4C, 5A and 5C, in the speaker module 300 according to one or more embodiments, a height of a shield member 410 may be expanded to a second height that is substantially the same as or greater than that of the speaker assembly 200. According to one or more embodiments, the shield member 410 (e.g., at least one of the first to fourth shield walls 411 to 414) may include a reference portion 410-1 that protrudes upward from the first surface (e.g., the upper surface) of the second speaker housing 314 to the first height along the first direction (e.g., the Z-axis direction), and an expansion portion 410-2 that extends from the reference portion 410-1 to the second height in the first direction. In other words, one end (e.g., one end of the reference portion 410-1) of the shield member 410 may contact the first surface of the second speaker housing 314. Additionally or optionally, an opposite end (e.g., one end of the expansion portion 410-2) of the shield member 410 may contact the inner surface of the first speaker housing 312.

When the second height of the shield member 410 is increased, the magnetic field introduced into the side surface of the speaker assembly 200 may be more effectively blocked. However, due to this structure, because the communication path 423 is not formed between the shield member 410 and the speaker assembly 200, at least a portion of the air flow between the speaker assembly 200 and the back volume 330 may be cut off (or blocked).

In this regard, at least one vent hole 500 may be formed in the shield member 410 according to one or more embodiments. According to one or more embodiments, as may be seen through the cross-sectional view of FIG. 5D, taken along line C-C of the electronic device of 3D, the speaker assembly 200 and the back volume 330 may be communicated with each other through the communication path 510 defined by at least one vent hole 500. At least one vent hole 500 may be formed in the expansion portion 410-2.

For example, as illustrated in FIG. 5A, at least one first vent hole 501 may be formed in the first shield wall 411 (or the expansion portion of the first shield wall 411), and at least one second vent hole 502 may be formed in the second shield wall 412 (or the expansion portion of the second shield wall 412). Accordingly, the speaker assembly 200 and the back volume 330 may be communicated with each other through at least one first communication path 510 defined by a first vent hole 501 and at least one second communication path 520 defined by a second vent hole 502.

As another example, as illustrated in FIG. 5B, at least one vent hole 500 may include at least one third vent hole 503 that is formed in the third shield wall 413 (or the expansion portion of the third shield wall 413) and at least one fourth vent hole 504 formed in the fourth shield wall 414 (or the expansion portion of the fourth shield wall 414). Accordingly, the speaker assembly 200 and the back volume 330 may be communicated with each other through at least one third communication path 530 defined by the third vent hole 503 and at least one fourth communication path 540 defined by the fourth vent hole 504.

According to various embodiments, the back volume 330 may be isolated (or separated) from the first sound output opening 312-2 of the speaker module 300. For example, a radiation path of the sound signal that outputs the sound signal through the first sound output opening 312-2 and the communication path 510 to 540 defined by the vent hole 500 may be isolated from each other by a partition formed in the first speaker housing 312 and the second speaker housing 314.

A shape of the vent hole 500 illustrated in FIGS. 5A and 5B is merely an example, and the shape of the vent hole 500 is not limited thereto. According to one or more embodiments, the number of vent holes 500 may be greater or smaller than the number of vent holes 500 illustrated, and the positions, in which the vent holes 500 are formed, and the sizes of the vent holes 500 may also be different from each other. For example, the vent hole 500 may be formed not only in the expansion portion 410-2 but also in the reference portion 410-1, or may be formed only in the reference portion 410-1 instead of the expansion portion 410-2. As another example, the vent hole 500 may be formed in all of the first to fourth shield walls 411 to 414. As another example, the vent hole 500 may be formed only in one of the shield walls, among the first to fourth shield walls 411 to 414. In this case, as illustrated in FIG. 5C, the vent hole (e.g., the second vent hole 500) may be formed in a shield wall (e.g., the second shield wall 412) that is located at a relatively long distance with respect to a direction 560, in which the magnetic field is generated, to minimize the magnetic field from being introduced into the speaker assembly 200.

As described above, when the height of the shield member 410 is increased, the magnetic field introduced into the side surface of the speaker assembly 200 may be more effectively blocked. However, because the shield member 410 is configured to surround only the side surface of the speaker assembly 200, a situation, in which the magnetic field is introduced through the upper surface of the speaker assembly 200, on which the shield member 410 is not formed, may occur.

In this regard, the speaker module 300 according to one or more embodiments may further include a structure that shields the upper surface of the speaker assembly 200.

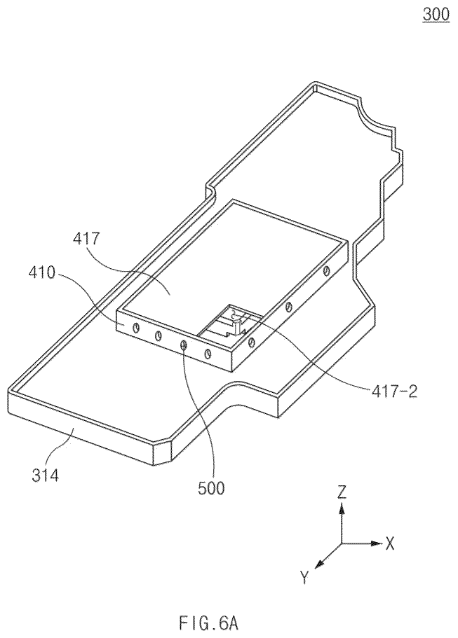

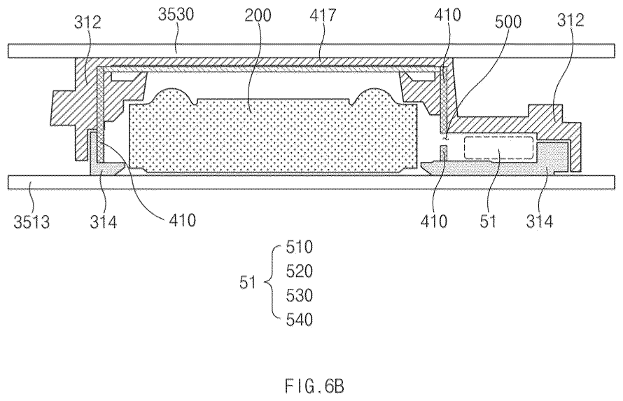

FIG. 6A is a diagram illustrating a speaker module having a magnetic field shielding structure according to one or more embodiments. FIG. 6B is a cross-sectional view of an electronic device having the speaker module illustrated in FIG. 6A, taken along line C-C, according to one or more embodiments.

Referring to FIGS. 6A and 6B, the speaker module 300 according to one or more embodiments may include a side surface shield member 410 that is configured to cover the side surface of the speaker assembly 200 and an upper shield member 417 that is configured to cover the upper surface of the speaker assembly 200.

According to one or more embodiments, the side surface shield member 410 may block a magnetic field from being introduced into the side surface of the speaker assembly 200. The side surface shield member 410 may have a height that is substantially the same as or greater than that of the speaker assembly 200 in the first direction (e.g., the Z-axis direction). According to one or more embodiments, the side surface shield member 410 may be formed to protrude upward from the first surface (e.g., the upper surface or the inner surface) of the second speaker housing 314 along the first direction. In other words, one end of the side surface shield member 410 may contact the first surface of the second speaker housing 314.

According to one or more embodiments, the upper shield member 417 may block a magnetic field from being introduced into the upper surface of the speaker assembly 200. The upper shield member 417 may contact an opposite end of the side surface shield member 410.

According to one or more embodiments, as may be seen from the cross-sectional view of FIG. 6B taken along line C-C of the electronic device of FIG. 3D, in which the speaker module 300 that surrounds a speaker assembly 200 by using the side surface shield member 410 and the upper shield member 417 is provided, a magnetic field may be blocked from being introduced into the side surface and the upper surface of the speaker assembly 200. Furthermore, the speaker assembly 200 and the back volume 330 may be communicated with each other through a communication path 510 defined by at least one vent hole 500 of the side surface shield member 410. However, the speaker assembly 200 may be closed (or isolated) by the side surface shield member 410 and the upper shield member 417, and thus, at least a portion of the air flow between the speaker assembly 200 and the back volume 330, and between the speaker assembly 200 and the first sound output opening 312-2 may be cut off (or blocked).

In this regard, at least one vent hole 500 may be formed in the side surface shield member 410 according to one or more embodiments. Accordingly, the speaker assembly 200 and the back volume 330 may be communicated with each other through at least one of the communication paths 510 to 540 defined by the at least one vent hole 500.

Additionally or optionally, a second sound output opening 417-2 may be formed in an area of the upper shield member 417 according to one or more embodiments. The second sound output opening 417-2 may be an opening that communicates an interior space of the shield member 410 and the outside. A sound signal generated by the speaker assembly 200 may be directed to the first sound output opening 312-2 through the second sound output opening 417-2.

According to one or more embodiments, the side surface shield member 410 and the upper shield member 417 may exist separately, but the upper shield member 417 may be formed integrally with the side surface shield member 410.

According to one or more embodiments, at least one of the side surface shield member 410 and the upper shield member 417 may be formed of a magnetic material. For example, a ferrite-based magnetic substance (e.g., SUS430, SPCC, or the like) may be used as the shield member 410 to improve the magnetic field shielding performance. Alternatively, as an example, at least a portion of at least one of the side surface shield member 410 and the upper shield member 417 may be formed of a ferrite-based magnetic substance. As an example, a portion (e.g., at least a portion of at least one of the side surface shield member 410 and the upper shield member 417) that is disposed close to a component of an electronic device 100, into which a magnetic field is introduced, may be formed of a ferrite-based magnetic substance, and another portion thereof may be formed of a metallic material (or a magnetic field shielding material other than the ferrite-based magnetic substance). The characteristics may be applied to at least a portion of the at least one shield member (e.g., at least a portion of the first to fourth shield walls) described in FIGS. 4A to 6B described above.

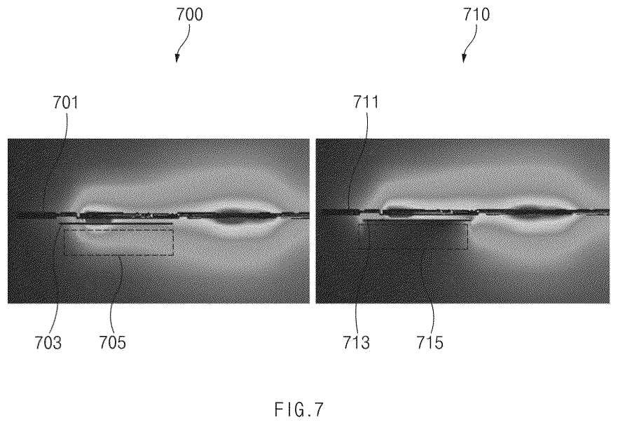

FIG. 7 is a diagram comparing a magnetic field shielding performance of shield members. That is, FIG. 7 is a comparison between a magnetic field shielding performance of a shield member according to one or more embodiments and a shield member according to a comparative example.

Reference numeral 700 of FIG. 7 denotes the magnetic field shielding performance for an electronic device 701 including a shield member 703 according to a comparative example formed of an austenitic magnetic substance (e.g., SUS304), and reference numeral 710 of FIG. 7 denotes the magnetic field shielding performance for an electronic device 711 including a shield member 713 according to one or more embodiments formed of a ferrite-based magnetic substance (e.g., SUS430).

In detail, as shown by 705 and 715 of FIG. 7, it may be identified that the magnetic field generated in the electronic device passes through the shield member 703 according to the comparative example, while it does not pass through the shield member 713 according to one or more embodiments.

It may be seen that when a shield member is formed using a ferrite-based magnetic substance, the magnetic field shielding performance may be improved compared to when a shield member is formed using a magnetic substance based on another material. The shield member (or the shield member, in which the ferrite-based magnetic substance is formed at least partially) using the ferrite-based magnetic substance described in FIG. 7 may be applied to at least a portion of the shield member described in FIGS. 4A to 6B described above. Furthermore, in FIGS. 3A to 7 described above, there may be portions described in a form limited to the corresponding drawings in describing the embodiments, but embodiments are not limited thereto, and the features described in a specific drawing may be applied to other drawings as well. For example, it may be understood that the structure of the electronic device described in FIG. 3D is a structure, to which at least some features of the shield member described in FIGS. 4A to 7 are applied. Also, the feature that the height of the at least one shield wall described in FIGS. 4B and 4C is different from the height of the upper surface of the speaker assembly may be partially applied to at least some (e.g., at least one of the third shield wall and the fourth shield wall) of the shield walls of FIG. 5A, at least some (e.g., at least one of the first shield wall and the second shield wall) of the shield walls of FIG. 5B, and at least some (e.g., at least one of the first shield wall, the third shield wall, or the fourth shield wall) of the shield walls of FIG. 5C. Similarly, the feature that the height of at least one shield wall described in FIGS. 4B and 4C is different from the height of the upper surface of the speaker assembly may be applied to at least some of the shield walls of FIG. 6a, in which no vent hole is formed.

As one or more embodiments, in the above description, the structure, in which the side surface shield member extends in an upward direction (e.g., a direction, in which the display is disposed, with respect to FIG. 3D) from a bottom surface of the second speaker housing 314 and the upper shield member covers the upper opening of the side surface shield member, has been described as an example, but embodiments are not limited thereto. For example, the side surface shield member and the upper shield member may be provided in an integrated form, and the integral cover type shield member may have at least some of the various features described above, for example, at least some of the feature that the height of the shield wall is different from the height of the upper surface of the speaker assembly, the feature that the vent hole is disposed to be declined to the upper side of the shield wall, and the structure, in which the second sound output opening 417-2 is formed, may be applied.

Referring to FIG. 3D as one or more embodiments, an electronic device (e.g., a portable terminal or a portable communication device), may have an output (e.g., a sound signal) of a speaker module through a side surface of a housing 3510 when the surface that faces the display, on which the screen is displayed, is a front surface. In this case, at least one hole may be formed on the side surface of the housing 3510 to be connected to the first sound output opening (e.g., 312-2 of FIG. 3B) of the speaker module (e.g., 300 of FIG. 3D). Here, embodiments are not limited to the shape and the disposition direction of the first sound output opening, and may have various shapes and disposition directions. For example, the first sound output opening connected to the second sound output opening 417-2 illustrated in FIG. 6A may be formed in a rearward direction of the housing 3510 illustrated in FIG. 3D. In this case, at least one hole corresponding to the first sound output opening (or a sound signal output through the first sound output opening) may be formed in the housing 3510 in a rearward direction (e.g., an opposite direction to the direction, in which the display is disposed).

A speaker module according to one or more embodiments may include a speaker housing including a first speaker housing defining at least a first surface of the speaker module and a second speaker housing defining at least a second surface of the speaker module being opposite to the least one first surface, a speaker assembly including a voice coil and a vibration member, and accommodated in an interior of the speaker housing, a back volume formed in an interior of the speaker housing through coupling of the first speaker housing and the second speaker housing, and a side surface shield member disposed between an inner surface of the speaker assembly and the back volume, and formed of a ferrite-based magnetic substance, and at least one vent hole communicating the speaker assembly and the back volume may be formed in the side surface shield member.

According to one or more embodiments, one end of the side surface shield member may contact the first speaker housing or the second speaker housing, and an opposite end of the side surface shield member may be formed to protrude toward the interior of the speaker housing.

According to one or more embodiments, the speaker module may further include an upper shield member connected to the opposite end of the side surface shield member, and disposed between an upper surface of the speaker assembly and the back volume.

According to one or more embodiments, the side surface shield member may be disposed to be spaced apart from an inner surface of the speaker assembly by a specific interval.

According to one or more embodiments, the upper shield member may be disposed to be spaced apart from an upper end surface of the speaker assembly by a specific interval.

According to one or more embodiments, a first sound output opening may be formed in an area of the first speaker housing, a second sound output opening communicating the speaker assembly and the first sound output opening may be formed in an area of the upper shield member, and a sound signal generated by the speaker assembly may be radiated to an outside via the second sound output opening and the first sound output opening.

According to one or more embodiments, the side surface shield member may include at least one of a first shield wall disposed between the first side surface of the speaker assembly and the speaker housing, a second shield wall disposed between the second side surface being opposite to the first side surface and the speaker housing, a third shield wall disposed between the third side surface connected from one end of the first side surface to one end of the second side surface and the speaker housing, or A fourth shield wall disposed between the fourth side surface being opposite to the third side surface and the speaker housing, and the at least one vent hole may be formed in at least one of the first shield wall, the second shield wall, the third shield wall, or the fourth side wall.

According to one or more embodiments, at least one of the first to fourth shield walls may include a reference portion having a first height being smaller than that of the upper surface of the speaker assembly, and an expansion portion expanded by a second height being greater than or equal to the height of the upper surface of the speaker assembly from the reference portion, and at least one vent hole may be formed in the expansion portion.

According to one or more embodiments, the at least one vent hole may be additionally formed in the reference portion.

According to one or more embodiments, the upper shield member may be formed of the ferrite-based magnetic substance.

An electronic device according to one or more embodiments may include a housing, a main board disposed inside the housing, and on which a plurality of components for an operation of the electronic device are mounted, and a speaker module disposed on the main board, the speaker module may include a speaker housing including a first speaker housing defining at least a first surface of the speaker module and a second speaker housing defining at least a second surface of the speaker module being opposite to the first surface, a speaker assembly including a voice coil and a vibration member, and accommodated in an interior of the speaker housing, a back volume formed in an interior of the speaker housing through coupling of the first speaker housing and the second speaker housing, and a side surface shield member disposed between an inner surface of the speaker assembly and the back volume, and formed of a ferrite-based magnetic substance, and at least one vent hole communicating the speaker assembly and the back volume may be formed in the side surface shield member.

According to one or more embodiments, one end of the side surface shield member may contact the first speaker housing or the second speaker housing, and an opposite end of the side surface shield member may be formed to protrude toward the interior of the speaker housing.

According to one or more embodiments, the side surface shield member may include at least one of a first shield wall disposed between the first side surface of the speaker assembly and the speaker housing, a second shield wall disposed between the second side surface being opposite to the first side surface and the speaker housing, a third shield wall disposed between the third side surface connected from one end of the first side surface to one end of the second side surface and the speaker housing, or a fourth shield wall disposed between the fourth side surface being opposite to the third side surface and the speaker housing, and the at least one vent hole may be formed in at least one of the first shield wall, the second shield wall, the third shield wall, or the fourth side wall.

According to one or more embodiments, the at least one vent hole may be formed in a side wall disposed at a distance being relatively distant from at least one of a plurality of components mounted on the main board, which generates a magnetic field.

According to one or more embodiments, the electronic device may further include an upper shield member connected to the opposite end of the side surface shield member, and disposed between an upper surface of the speaker assembly and the back volume.

According to one or more embodiments, a first sound output opening may be formed in an area of the first speaker housing, and a speaker hole communicated with the first sound output opening may be formed in the housing.

According to one or more embodiments, a second sound output opening communicating the speaker assembly and the first sound output opening may be formed in an area of the upper shield member.

According to one or more embodiments, at least one of the first to fourth shield walls may include a reference portion having a first height being smaller than that of the upper surface of the speaker assembly, and an expansion portion expanded by a second height being greater than or equal to the height of the upper surface of the speaker assembly from the reference portion toward the interior of the speaker housing, and at least one vent hole may be formed in the expansion portion.

According to one or more embodiments, the at least one vent hole may be additionally formed in the reference portion.

According to one or more embodiments, the upper shield member may be formed of the ferrite-based magnetic substance.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

The embodiments of the disclosure disclosed in the specification and the drawings provide merely specific examples to easily describe technical content according to the embodiments of the disclosure and help the understanding of the embodiments of the disclosure, not intended to limit the scope of the embodiments of the disclosure. Accordingly, the scope of various embodiments of the disclosure should be interpreted as encompassing all modifications or variations derived based on the technical spirit of various embodiments of the disclosure in addition to the embodiments disclosed herein.

What is claimed is:

1. A speaker module comprising:
a speaker housing comprising a first speaker housing defining at least one first surface of the speaker module and a second speaker housing defining at least one second surface of the speaker module that is opposite to the least one first surface;
a speaker assembly comprising a voice coil and a vibration member, the speaker assembly being accommodated in an interior of the speaker housing;
a back volume in an interior of the speaker housing and defined by the first speaker housing and the second speaker housing; and
a side surface shield member between an inner surface of the speaker assembly and the back volume, the side surface shield member comprising a ferrite-based magnetic substance,
wherein at least one vent hole communicating the speaker assembly and the back volume is in the side surface shield member.

2. The speaker module of claim 1, wherein a first end of the side surface shield member contacts the first speaker housing or the second speaker housing, and
wherein a second end of the side surface shield member protrudes toward the interior of the speaker housing, the second end being opposite to the first end.

3. The speaker module of claim 2, further comprising:
an upper shield member connected to the second end of the side surface shield member, and between an upper surface of the speaker assembly and the back volume.

4. The speaker module of claim 3, wherein the upper shield member is spaced apart from an upper end surface of the speaker assembly by a predetermined interval.

5. The speaker module of claim 3, further comprising:
a first sound output opening in an area corresponding to the first speaker housing; and
a second sound output opening in an area corresponding to the upper shield member, the second sound output opening communicating the speaker assembly and the first sound output opening,
wherein a sound signal generated by the speaker assembly is radiated to an outside via the second sound output opening and the first sound output opening.

6. The speaker module of claim 3, wherein the side surface shield member comprises at least one of a first shield wall between a first side surface of the speaker assembly and the speaker housing, a second shield wall between a second side surface of the speaker assembly that is opposite to the first side surface and the speaker housing, a third shield wall between a third side surface of the speaker assembly that is connected from one end of the first side surface to one end of the second side surface and the speaker housing, and a fourth shield wall between a fourth side surface of the speaker assembly that is opposite to the third side surface and the speaker housing, and
wherein the at least one vent hole is in at least one of the first shield wall, the second shield wall, the third shield wall, and the fourth shield wall.

7. The speaker module of claim 6, wherein at least one of the first shield wall, the second shield wall, the third shield wall, and the fourth shield wall comprises:
a reference portion having a first height being smaller than a height of the speaker assembly; and
an expansion portion on the reference portion,
wherein the reference portion and the expansion portion together have a second height that is greater than or equal to the height of the speaker assembly, and
wherein at least one vent hole is in the expansion portion.

8. The speaker module of claim 7, wherein at least one vent hole is in the reference portion.

9. The speaker module of claim 3, wherein the upper shield member comprises the ferrite-based magnetic substance.

10. The speaker module of claim 1, wherein the side surface shield member is spaced apart from the inner surface of the speaker assembly by a predetermined interval.

11. An electronic device comprising:
a housing;
a main board inside the housing; and
a speaker module on the main board,
wherein the speaker module comprises:
a speaker housing comprising a first speaker housing defining at least one first surface of the speaker module and a second speaker housing defining at least one second surface of the speaker module that is opposite to the at least one first surface;
a speaker assembly comprising a voice coil and a vibration member, the speaker assembly being accommodated in an interior of the speaker housing;
a back volume in an interior of the speaker housing and defined by the first speaker housing and the second speaker housing; and
a side surface shield member between an inner surface of the speaker assembly and the back volume, the side surface shield member comprising a ferrite-based magnetic substance, and
wherein at least one vent hole communicating the speaker assembly and the back volume is in the side surface shield member.

12. The electronic device of claim 11, wherein a first end of the side surface shield member contacts the first speaker housing or the second speaker housing, and
wherein a second end of the side surface shield member protrudes toward the interior of the speaker housing, the second end being opposite to the first end.

13. The electronic device of claim 12, further comprising:
an upper shield member connected to the second end of the side surface shield member, and between an upper surface of the speaker assembly and the back volume.

14. The electronic device of claim 13, wherein a first sound output opening is in an area of the first speaker housing, and
wherein a speaker hole communicated with the first sound output opening is in the housing.

15. The electronic device of claim 14, wherein a second sound output opening communicating the speaker assembly and the first sound output opening is in an area of the upper shield member.

16. The electronic device of claim 13, wherein the upper shield member comprises the ferrite-based magnetic substance.

17. The electronic device of claim 11, wherein the side surface shield member comprises at least one of a first shield wall between a first side surface of the speaker assembly and the speaker housing, a second shield wall between a second side surface of the speaker assembly that is opposite to the first side surface and the speaker housing, a third shield wall between a third side surface of the speaker assembly that is connected from one end of the first side surface to one end of the second side surface and the speaker housing, and a fourth shield wall between a fourth side surface of the speaker assembly that is opposite to the third side surface and the speaker housing, and
wherein the at least one vent hole is in at least one of the first shield wall, the second shield wall, the third shield wall, and the fourth shield wall.

18. The electronic device of claim 17, wherein the at least one vent hole is in the second shield wall and is spaced apart from at least one of a plurality of components mounted on the main board that generates a magnetic field.

19. The electronic device of claim 17, wherein at least one of the first shield wall, the second shield wall, the third shield wall and the fourth shield wall comprises:
a reference portion having a first height being smaller than a height of the speaker assembly; and
an expansion portion on the reference portion,
wherein the reference portion and the expansion portion together have a second height that is greater than or equal to the height of the speaker assembly, and
wherein at least one vent hole is in the expansion portion.

20. The electronic device of claim 19, wherein at least one vent hole is in the reference portion.
